(19) United States
(12) Patent Application Publication
(10) Pub. No.: US 2007/0026605 A1
(43) Pub. Date: Feb. 1, 2007

(54) Fabricating approach for memory device

(75) Inventors: Jen-Chun Pan, Kaohsiung city (TW); Chong-Jen Huang, Sanchong City (TW)

Correspondence Address: MACRONIX;C/O HAYNES BEFFELL & WOLFELD LLP, P. O. BOX 366, HALF MOON BAY, CA, 94019, US

(73) Assignee: Macronix International Co., Ltd., Hsinchu (TW)

(21) Appl. No.: 11/194,713

(22) Filed: Aug. 1, 2005

(51) Int. Cl. H01L 21/336; H01L 21/331

(52) U.S. Cl. 438/257; 438/314; 257/E27.102

(57) ABSTRACT

To address problems encountered during the fabrication of a nonvolatile memory cell, such as preventing top oxide loss, preventing contact between the nitride and the polysilicon, and reducing the problem of BD over-diffusion, various fabrication embodiments are used. In one approach, the top dielectric of an ONO structure is formed at the same time as the oxide covering the implanted regions. In another approach, another dielectric structure is formed on the implanted regions and on the top oxide of the charge storage structure. In yet another approach, a cleaning process following ion implantation is performed prior to forming the top oxide of the ONO structure. These approaches also apply to floating gate nonvolatile memories.

### BACKGROUND

1. Field of the Invention

The present invention relates to the fabrication of semiconductor devices and, more particularly, to the fabrication of non-volatile memory devices.

2. Description of Related Art

Various memory devices for non-volatile storage of information, such as read only memory (ROM), programmable read only memory (PROM), erasable programmable read only memory (EPROM), and other advanced memory devices, are currently used. Other advanced memory devices that involve more complex processing and testing procedures include electrically erasable programmable read only memory (EEPROM), and nitride-read-only memory. These advanced memory devices can accomplish tasks that are beyond the capabilities of ROM. For example, the use of EEPROM devices in circuitry permits in-circuit erasing and reprogramming of the device.

FIG. 1A is a cross-sectional view of a conventional nitride read-only memory cell 30. The substrate 10 is implanted with a source 12 and a drain 14. On top of substrate 10 lies a sandwich structure having a nitride layer 17 between a top oxide layer 16 and a bottom oxide layer (tunneling oxide layer) 18, known as an ONO structure. A number of oxides 20 are formed to isolate adjacent ONO structures and separate the channels 22. The nitride read-only memory cell structure depicted in FIG. 1A contains multiple bits in one cell, and is also referred to as N-Bit memory. The larger region encircled with the dashed line denotes an N-Bit memory cell 30, and the two smaller regions each encircled with a dashed line denote the first bit 32 and the second bit 34. Although each region 32 and 34 is referred to as a bit, each region 32 and 34 is capable of storing multiple logical bits if each region is associated with at least 4 levels of threshold voltage.

The N-Bit memory device generally contains a memory array and a peripheral portion. The peripheral portion includes logic circuits outside the array, such as the decoder, sense circuitry, protection circuitry, pumping circuitry, and HV/LV circuitry. In a conventional process, the memory array is fabricated before the peripheral portion of the N-Bit memory device. First, the ONO structure is added on the entire array, after which the ONO structure is etched according to a predetermined pattern from selected portions of the semiconductor substrate. The buried diffusions (BDs) which function as bit lines are formed by implanting the source and drain in the portions of the semiconductor substrate from which portions of the ONO structure have been etched.

After the fabrication of the memory array, the peripheral portion is implanted and the well is formed. The portions of the ONO structure over the peripheral portion are removed, after which oxide, also called BD oxide, is grown on the top of the BD. Following the oxidation in the peripheral portion, polysilicon is deposited on the ONO structure of the memory array and the BD oxide.

However, there are several drawbacks in the conventional fabricating process. For example, an N-Bit cell with multiple oxide layers may have a buried diffusion problem, as shown in FIG. 1B. In the conventional process, phosphorus or arsenic ions are implanted and the source 12 and drain 14 are originally kept away from each other at a distance of d. A thermal process such as conventional furnace oxidation causes diffusion of the implanted ions of the source 12 and drain 14, effectively resulting in an enlarged source 12′ and drain 14′, associated with a shorter distance between of d′ between the enlarged source 12′ and drain 14′. Similarly, after executing more thermal processes or using thermal processes which take more time, the source 12′ and drain 14′ further diffuse, resulting in further enlarged source 12″ and drain 14″, with a further reduced distance d″ in between. Thus the over-diffusion problem shortens the length of the channel between the source and the drain. Additionally, after BD oxide growth by furnace oxidation, the end of the ONO structure 36 closer to the sidewall easily expands. Due to the position of the BD oxide, the end of the ONO structure 36 warps upward, as shown in FIG. 1C. In this situation, the silicon nitride structure (the middle of the ONO structure 36, labeled “N”) touches the polysilicon structure after the polysilicon structure 24 is formed. The N-Bit memory device will have poor reliability if the silicon nitride contacts the polysilicon. Also, for an N-Bit memory device that requires multiple layers of oxide, the top oxide layer will be exposed to cleaning solution several times in the cleaning procedure. The resulting oxide layer is thinner and has poor quality due to damage resulting from the cleaning procedure.

### SUMMARY

Various embodiments provide methods of fabricating non-volatile memory cell, thereby addressing problems such as top oxide loss, contact between the nitride and the polysilicon, and BD over-diffusion.

In one embodiment, a semiconductor substrate is provided. A first dielectric structure is formed on the substrate, and a charge storage structure is formed on the dielectric structure. These two structures are the lower two parts of an ONO structure. These two structures are removed over selected portions of the substrate without removing them from the unselected portions of the substrate, and then the dopants are implanted into the selected portions of the semiconductor substrate, forming the sources and drains of the memory cells. A dielectric structure is then formed over the selected and unselected portions of the implanted semiconductor substrate, simultaneously forming the top oxide of the ONO structures and isolating the separate memory devices.

In another embodiment, the top dielectric is formed on the charge storage structure prior to removing the ONO structure over selected portions of the substrate, implanting into the selected portions of the semiconductor substrate, and forming another dielectric structure on the selected portions of the semiconductor substrate and the top oxide of the charge storage structure, such as via ISSG. Performing the ISSG process helps to anneal the damage caused by cleaning the implanted areas. Performing the ISSG process helps strong oxidation for better oxide quality above the implanted regions, and isolation between the storage and conductive structures.

In another embodiment, after dopants are implanted into the selected portions of the semiconductor substrate from which the charge storage and lower oxide structures have been removed, the now exposed implanted portions of the semiconductor substrate with the implanted dopants and the charge storage structure are cleaned simultaneously. By performing the cleaning process prior to forming the top oxide of the ONO structure, the top oxide escapes damage which would otherwise occur during the cleaning process.

If the oxide formed after performing ISSG is too thin, a furnace oxidation increases the thickness of the oxide covering the BD regions.

Other objects, features, and advantages of the invention will become apparent from the following detailed description of the preferred but non-limiting embodiment. The following description is made with reference to the accompanying drawings.

### BRIEF DESCRIPTION OF THE DRAWINGS

FIG. 1A is a cross-sectional view of conventional N-Bit memory cells;

FIG. 1B shows over-diffusion of the implanted source and drain in a conventional N-Bit memory cell;

FIG. 1C shows the ONO structure expansion in a conventional N-Bit memory cell;

FIGS. 2A˜2D show cross-sectional views throughout a process for fabricating the N-Bit memory cell;

FIGS. 3A˜3D show cross-sectional views throughout another process for fabricating the N-Bit memory cell;

FIG. 4 shows a process flow for fabricating the N-Bit memory cell;

FIG. 5 shows another process flow for fabricating the N-Bit memory cell;

FIG. 6 shows a simplified schematic of an integrated circuit with the described nonvolatile memory; and

FIG. 7 shows a graph of electrical breakdown versus implantation energy.

### DETAILED DESCRIPTION

The silicon nitride structure that performs charge trapping is covered with oxide along the top, bottom, and sidewall. The invention includes embodiments of N-Bit memory cell fabrication described herein and other embodiments covered by the claims. Accordingly, the specification and the drawings are to be regarded as illustrative sense rather than restrictive.

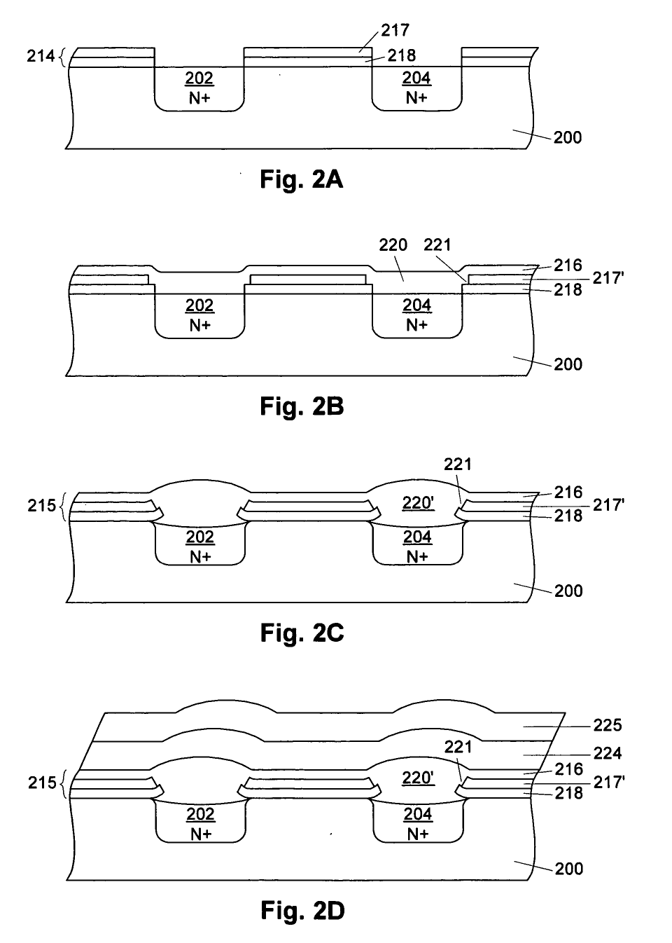

FIGS. 2A˜2D show cross-sectional views throughout a process for fabricating the N-Bit memory cell.

As illustrated in FIG. 2A, a semiconductor substrate 200 is provided and bottom oxide layer 218 is formed. Then a silicon nitride layer 217 for charge storage is formed thereon. Other representative charge trapping structures are similar high dielectric constant materials, including metal oxides such as Al₂O₃, HfO₂, and others. The charge trapping structure may be a discontinuous set of pockets or particles of charge trapping material, or a continuous layer as shown in the drawing. Together, the patterned bottom oxide layer 218 and silicon nitride layer 217 form NO structure 214. After patterning the silicon nitride layer 217 by etching portions of the nitride layer 217 and the bottom oxide 218 covering selected portions of the substrate 200, the BD (buried diffusion) areas (202/204) are formed by a traditional ion implantation process in the selected portions of the substrate 200 that are now exposed.

Referring to FIG. 2B, by deposition or in-situ steam generation (ISSG) processes, an oxide layer 220 is formed to cover the patterned nitride layer 217 and bottom oxide 218 and the exposed BD regions 202 and 204. ISSG, a new technique with a low thermal budget, is employed to oxidize silicon nitride and silicon into silicon oxide. Based on the different oxidation rates of silicon nitride and silicon, the oxide grown by the BD regions 220 is thicker than the top oxide 216 grown on nitride layer 217′. Because silicon nitride is oxidized by the ISSG process, an oxide film 221 is formed on the sidewall of the charge trapping layer. Silicon oxide covers the silicon nitride film 217′ along its surface and side wall, and the silicon nitride 217′ that traps charge won't touch the polysilicon when the end of the silicon nitride 217′ and bottom oxide 218 warp upward into the expanding BD oxide 220′ during the BD oxide growth process discussed in connection with FIG. 2C. The top portion of silicon nitride can be oxidized by ISSG, and produces the ONO structure that is shown in FIG. 2B.

In FIG. 2C, to optimize the thickness of the oxide covering the BD region 220, a furnace oxidation process is performed. There is nearly no silicon nitride 217′ oxidized during this process, but doped silicon covering the BD regions is oxidized. BD oxide is formed to isolate the adjacent gate structures, and the thickness of BD oxide 220 is adjusted to 220′ for sufficient isolation between adjacent devices. If there is no need for BD oxide 220 to be grown thicker (e.g., to 220′), this oxidation process step can be omitted.

As shown in FIG. 2D, doped polysilicon is deposited on the ONO layer 115 to form a polysilicon layer 224. The polysilicon layer 224 can be doped by phosphorus or arsenic ions and can be capped by metal silicide 225, e.g. tungsten silicide (WSiX), titanium silicide (TiSiX), nickel silicide (NiSiX), or cobalt silicide (CoSiX).

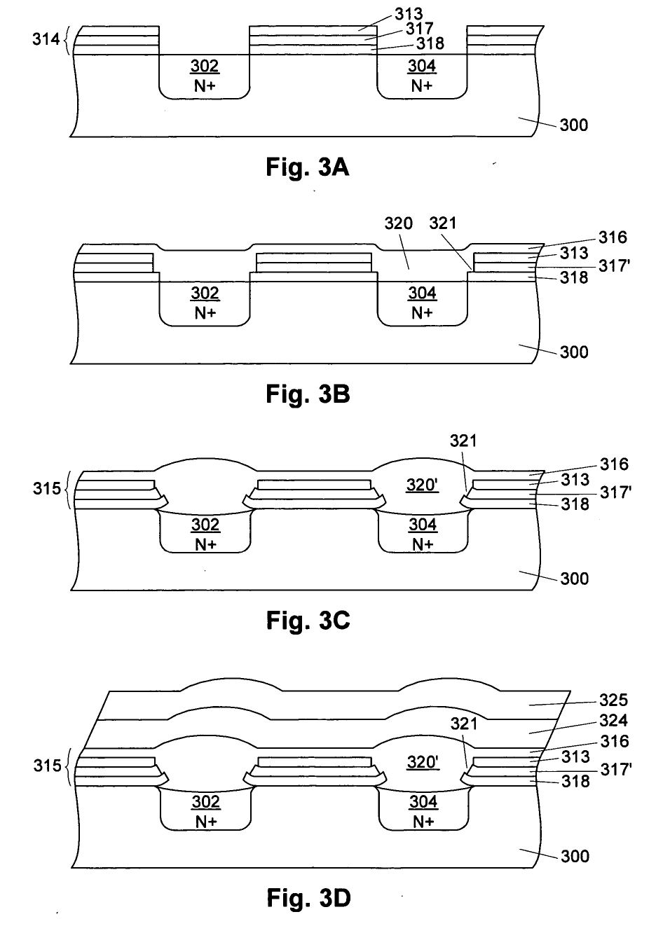

FIGS. 3A˜3D show cross-sectional views throughout another process for fabricating the N-Bit memory cell. FIGS. 3A˜3D differ from FIGS. 2A˜2D in that a top oxide 313 is formed on the nitride 317, prior to etching parts of the ONO structure 314 above selected portions of the semiconductor substrate 300, implanting ions into BD regions 302 and 304, and performing growth of ISSG oxide 320. In other embodiments, the nitride structure is replaced with a conductive structure such as polysilicon to store charge.

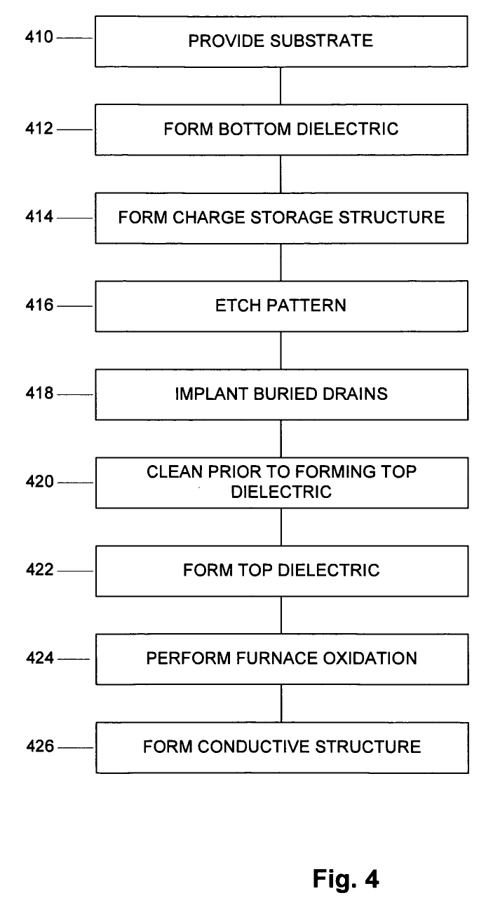

FIG. 4 shows a process flow for fabricating the N-Bit memory cell. In 410, a semiconductor substrate is provided. In 412, a bottom dielectric is formed. In 414, a charge storage structure is formed. In 416, a pattern is etched into the bottom dielectric and charge storage structure that cover selected portions of the semiconductor substrate. In 418, dopants are implanted into the now exposed selected portions of the semiconductor substrate, forming the buried drains (source and drain). In 420, prior to forming the top dielectric on the charge storage structure, remaining photoresist is stripped and the exposed areas (the implanted selected portions of the semiconductor substrate and the charge storage structure) are cleaned. One example of stripping is a wet strip procedure that combines H₂SO₄ for 580 seconds, NH₄OH for 540 seconds at 80 C, and 35 C. This removes around 10A of oxide. One example of cleaning combines NH₄OH for 6 minutes, HCl for 6 minutes at 45 C, and 45 C. This removes around 10A of oxide. In 422, the top dielectric is formed on the charge storage structure via ISSG. At this time, oxide growth also occurs above the implanted BD regions. In this way, time is saved that would otherwise be spent performing furnace oxidation to form the top oxide of the ONO structures. Performing the ISSG oxide growth after cleaning results in ISSG oxide that is undamaged by cleaning. Also at this time, the implanted BD surface is annealed to repair damage from the implantation process. The ISSG grown oxide has a high electrical breakdown value of over 8 MV/cm. Sample conditions for the ISSG oxide growth are: H2 flow rate of 0.45-0.55 L/min, O2 flow rate of 8.5-10.5 L/min, pressure range of 8-10 torr, temperature range of 940-960° C, time range of 111-131 sec, and growth rate of 36-38 Å/min. In 424, furnace oxidation is performed to grow the oxide above the implanted BD regions to an optimal thickness. In 426, conductive structures are formed, usually polysilicon corresponding to word lines.

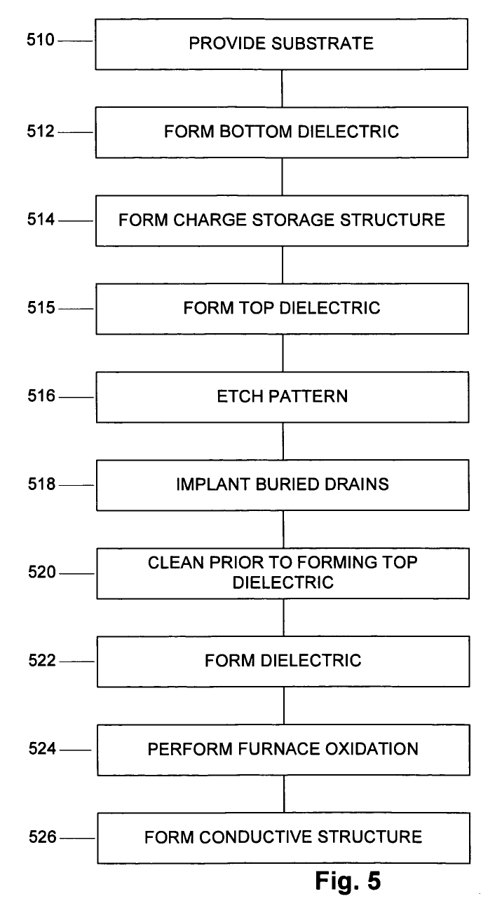

FIG. 5 shows another process flow for fabricating the N-Bit memory cell. Unlike the process of FIG. 4, in FIG. 5 the top dielectric is formed in 515, prior to etching selected portions of the ONO structure in 516. By delaying the formation of polysilicon until 526, after dielectric is grown over the implanted BD regions and the top oxide of the ONO structure, the topography of the memory array is improved. The topography is flatter because the dielectric is grown prior to the formation of a conductive structure such as polysilicon. In embodiments other than FIGS. 4 and 5, the nitride structure is replaced with a conductive structure such as polysilicon to store charge.

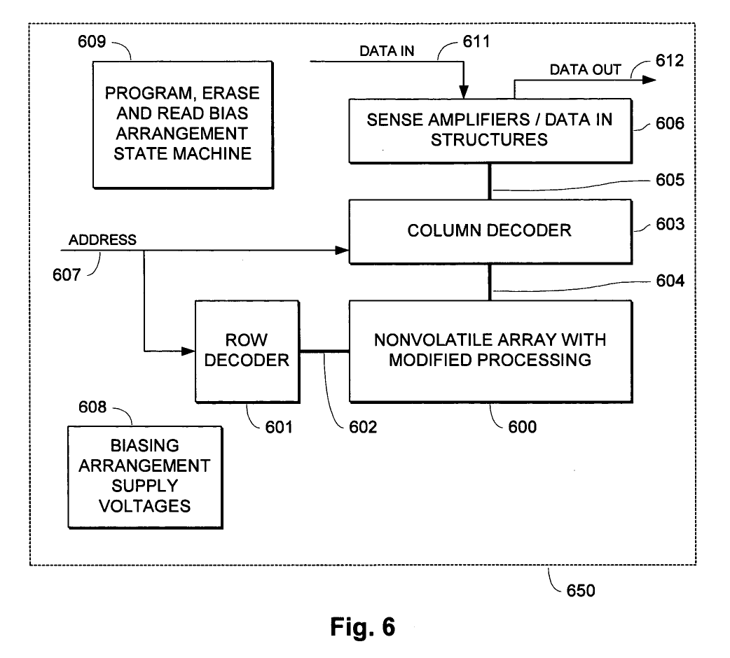

FIG. 6 shows a simplified schematic of an integrated circuit with the nonvolatile memory described herein. The integrated circuit 650 includes a memory array 600 implemented using charge trapping memory cells, on a semiconductor substrate. The memory array is fabricated by using a process such as ISSG to grow oxide above the BD regions and the charge trapping structures at a same time, or using a process such as ISSG to grow oxide above the BD regions and the top oxide of the ONO structure at a same time, or cleaning the implanted BD regions and the charge storage structure at a same time. A row decoder 601 is coupled to a plurality of word lines 602 arranged along rows in the memory array 600. A column decoder 603 is coupled to a plurality of bit lines 604 arranged along columns in the memory array 600. Addresses are supplied on bus 605 to column decoder 603 and row decoder 601. Sense amplifiers and data-in structures in block 606 are coupled to the column decoder 603 via data bus 607. Data is supplied via the data-in line 611 from input/output ports on the integrated circuit 650, or from other data sources internal or external to the integrated circuit 650, to the data-in structures in block 606. Data is supplied via the data-out line 615 from the sense amplifiers in block 606 to input/output ports on the integrated circuit 650, or to other data destinations internal or external to the integrated circuit 650. A bias arrangement state machine 609 controls the application of bias arrangement supply voltages 608, such as for the erase verify and program verify voltages, and the arrangements for programming, erasing, and reading the memory cells.

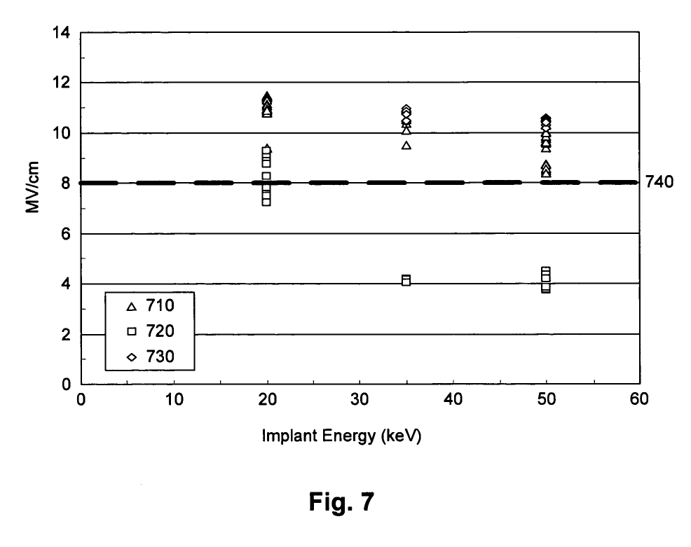

FIG. 7 shows a graph of electrical breakdown versus implantation energy. The data points 710 are measured with a wafer corresponding to the process flow of FIG. 5. The data points 730 are measured with a wafer corresponding to the process flow of FIG. 4. The data points 720 are measured with a wafer having thermally grown oxide over the BD regions, with no oxide grown by ISSG. The hyphenated line 740 corresponds to the breakdown voltage of unetched ONO structures. The data indicate that the strongest oxide is fabricated with ISSG oxide growth of the BD region oxide and the top oxide of the ONO structures at the same time. The data also indicate that a strong oxide is fabricated with ISSG oxide growth of the BD region oxide and a third oxide on top of an existing top oxide of the ONO structures at the same time.

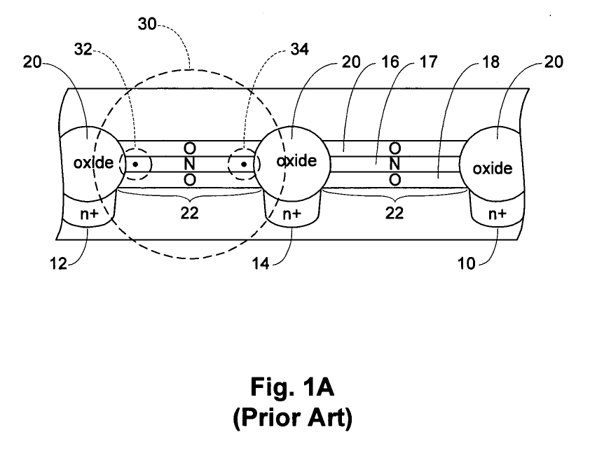

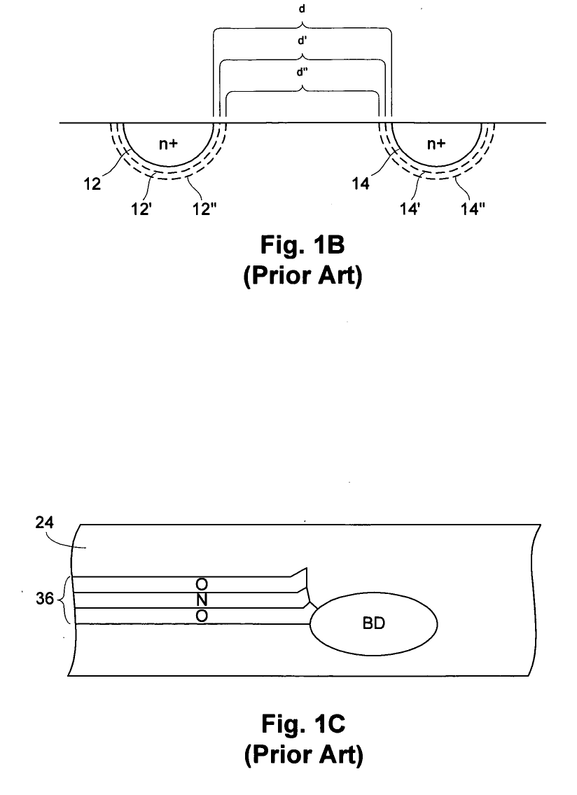

In comparison with the conventional N-Bit memory cell (FIG. 1A), embodiments of the fabricated N-Bit memory cell remain discrete and contain multiple bits in a cell. In contrast with the conventional cell, in embodiments of the N-Bit memory, a pre-oxidation process such as ISSG for BD oxide is performed. ISSG is well known for forming an ultra-thin gate insulator layer so that the top oxide of the N-Bit memory cell has better quality than that of conventional oxide. ISSG shortens fabrication by hours, during which the wafers would otherwise be treated in a conventional furnace for BD oxide growth. Using the pre-oxidation process via ISSG with a low thermal budget in fabrication, the condition of buried drain (BD) over-diffusion (as shown in FIG. 1B) can be reduced, and the length of the channel can also be controlled more precisely. Also, the ONO layer expansion and upward warping causing bird's beak (FIG. 1C) is not as bad in contrast with a conventional cell. Because the coverage from the bird's beak decreases and the side walls of the ONO structure are oxidized by ISSG in the N-Bit memory cell, the insulated oxide layer can successfully isolate the silicon nitride from the polysilicon, solving the problem arising from contact between the silicon nitride and polysilicon.

Thus, embodiments of fabricating nitride-read-only memory cell have several advantages, such as preventing top oxide loss, preventing contact between the nitride and the polysilicon, and reducing the problem of BD over-diffusion.

While the embodiments described above describe a dielectric-charge storage-dielectric structure of ONO, other embodiments are directed to other dielectric-charge storage-dielectric structures, such as SiO₂-polysilicon-SiO₂.

While the invention has been described by way of example and in terms of various embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a non-volatile memory cell comprising:
providing a semiconductor substrate;
forming a first dielectric structure on said substrate;
forming a charge storage structure on said dielectric structure;
removing the first dielectric structure and the charge storage structure covering selected portions of the semiconductor substrate without removing the first dielectric structure and the charge storage structure covering unselected portions of the semiconductor substrate;
after said removing, implanting dopants into the selected portions of the semiconductor substrate; and
after said implanting, forming a second dielectric structure over selected and unselected portions of the semiconductor substrate.

2. The method of claim 1, further comprising:
forming a conductive structure on the second dielectric structure.

3. The method of claim 1, wherein the charge storage structure is conductive.

4. The method of claim 1, wherein the charge storage structure is made of polysilicon.

5. The method of claim 1, wherein the charge storage structure traps charge.

6. The method of claim 1, wherein the charge storage structure is made of a nitride.

7. The method of claim 1, wherein said forming the second dielectric structure includes performing in-situ steam generation (ISSG) on the selected portions of the semiconductor substrate and the charge storage structure.

8. The method of claim 1, wherein the charge storage structure is made of a nitride, and said forming the second dielectric structure includes performing in-situ steam generation (ISSG) on the selected portions of the semiconductor substrate and the charge storage structure.

9. The method of claim 1, further comprising:
performing furnace oxidation after forming the second dielectric structure.

10. The method of claim 1, wherein the second dielectric structure has an electrical breakdown over 6 MV/cm.

11. The method of claim 1, wherein the third dielectric structure, the charge storage structure, and the first dielectric comprise an oxide-nitride-oxide structure.

12. The method of claim 1, further comprising:
after said forming the charge storage structure but before said removing, forming a third dielectric structure on said charge storage structure,
wherein said removing also removes the third dielectric structure such that said removing removes the third dielectric structure, the charge storage structure, and the first dielectric structure covering the selected portions of the semiconductor substrate.

13. The method of claim 1, further comprising:
after said forming the charge storage structure but before said removing, forming a third dielectric structure on said charge storage structure,
wherein said removing also removes the third dielectric structure such that said removing removes the third dielectric structure, the charge storage structure, and the first dielectric structure covering the selected portions of the semiconductor substrate,
wherein the third dielectric structure, the charge storage structure, and the first dielectric comprise an oxide-nitride-oxide structure.

14. A method for manufacturing a non-volatile memory cell comprising:
providing a semiconductor substrate;
forming a first dielectric structure on said substrate;
forming a charge storage structure on said dielectric structure;
removing the first dielectric structure and the charge storage structure covering selected portions of the semiconductor substrate;
implanting dopants into the selected portions of the semiconductor substrate; and
after said implanting, cleaning the selected portions of the semiconductor substrate with the dopants and the charge storage structure at a same time.

15. The method of claim 14, further comprising:
forming a second dielectric structure on the selected portions of the semiconductor substrate and the charge storage structure.

16. The method of claim 14, further comprising:
forming a second dielectric structure on the selected portions of the semiconductor substrate and the charge storage structure, the second dielectric structure having an electrical breakdown over 6 MV/cm.

17. The method of claim 14, further comprising:
forming a second dielectric structure on the selected portions of the semiconductor substrate and the charge storage structure; and
forming a conductive structure on the second dielectric structure.

18. The method of claim 14, wherein the charge storage structure is conductive.

19. The method of claim 14, wherein the charge storage structure is made of polysilicon.

20. The method of claim 14, wherein the charge storage structure traps charge.

21. The method of claim 14, wherein the charge storage structure is made of a nitride.

22. The method of claim 14, further comprising:
forming a second dielectric structure by performing in-situ steam generation (ISSG) on the selected portions of the semiconductor substrate and the charge storage structure.

23. The method of claim 14, wherein the charge storage structure is made of a nitride, and further comprising:
forming a second dielectric structure by performing in-situ steam generation (ISSG) on the selected portions of the semiconductor substrate and the charge storage structure.

24. The method of claim 14, further comprising:
forming a second dielectric structure on the selected portions of the semiconductor substrate and the charge storage structure; and
performing a furnace oxidation after forming the second dielectric structure.
